(19) United States
(12) Patent Application Publication
(10) Pub. No.: US 2006/0144567 A1
(43) Pub. Date: Jul. 6, 2006

(54) Pulsating heat transfer apparatus

(75) Inventors: Xi-Jian Zhu, ShenZhen (CN); Ching-Bai Hwang, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Foxconn Technology CO., LTD., Tu-Cheng City (TW)

(21) Appl. No.: 11/209,929

(22) Filed: Aug. 23, 2005

(30) Foreign Application Priority Data
Dec. 31, 2004 (TW) 93141687

(51) Int. Cl. H05K 7/20

(52) U.S. Cl. 165/104.29; 361/700

(57) ABSTRACT

A pulsating heat transfer apparatus includes a number of separate heat receiving portions (100, 200, 300), at least one heat dissipating portion (400), and a plurality of capillary pipes (500). Each heat receiving portion has a flat surface for contacting with a heat source, and defines therein at least one first capillary passage. Each heat dissipating portion defines therein at least one second capillary passage. The first capillary passages, the at least one second capillary passage, together with the capillary pipes form a close-looped, serpentine flow channel having capillary effect. Vapor slugs (600) and liquid slugs (700) are distributed in the flow channel. Heat is capable of being transferred from the heat receiving portions to the at least one heat dissipating portion by pulsation of the vapor slugs and liquid slugs.

### BACKGROUND OF THE INVENTION

1. Field of the Invention

The present invention relates generally to a heat transfer apparatus, and more particularly, relates to a pulsating heat transfer apparatus which has a flow channel with vapor and liquid slugs filled therein and transfers heat by pulsation of the vapor and liquid slugs.

2. Description of Related Arts

As ICs (Integrated Circuits) such as computer CPUs (Central Processing Units) are being designed to run faster and faster, more and more heat are being generated by these ICs. Traditional cooling techniques such as, for example, forced air cooling technique which typically comprises combined cooling fan and heat sink, are increasingly incompetent to timely remove the heat from the ICs. Under this background, heat pipe cooling technology is becoming increasingly popular due to its advantages over the traditional cooling techniques. These advantages mainly include high efficiency of heat removing, low level of noise and low level of power consumption.

The conventional heat pipe is typically formed by a pipe, a capillary structure or wick, and a working fluid. The pipe is generally made of a straight metal tube. The capillary structure is generally hollow and made of porous material. The capillary structure adheres to an inner wall of the pipe and forms a hollow channel for a vapor of the working fluid to move therein. The working fluid, such as alcohol, methyl alcohol or water, fills in the capillary structure. One end of the heat pipe serves as an evaporator, and the other end of the heat pipe serves as a condenser. The working principle of the conventional heat pipe is typically the following: when the evaporator is heated by a heat source, the liquid working fluid absorbs the heat and evaporates into a vapor. The vapor then flows in the channel of the capillary structure from the evaporator to the condenser. In the condenser, the vapor then dissipates heat and condenses into a liquid; the liquid penetrates into the capillary structure. The condensed liquid is driven back to the evaporator through the capillary structure by a capillary driving force to complete an evaporation and condensation cycle. As such, repeat evaporation and condensation cycles continuously take the heat away from the heat source.

In the traditional heat pipe, the capillary structure functions to pull the condensed liquid back to the evaporator and therefore is indispensable to the heat pipe. Unfortunately, the capillary structure limits the length of the heat pipe and thus limits the distance of heat transfer. In addition, formation of the capillary structures imposes a cost and difficulty in manufacturing the heat pipe.

U.S. Pat. No. 4,921,041 (issued in 1990) and U.S. Pat. No. 5,219,020 (issued in 1993), both filed by Akachi, Japan, each discloses a heat pipe operated with a new principle to improve the defects of the aforementioned traditional heat pipe. The heat pipe taught by Akachi has multiple pipes interconnected to form a closed, serpentine loop. The pipes are designed as capillary tubes in order to provide capillary effect without capillary structures formed therein. This is achieved by having the pipes with a small inner diameter so that the working fluid can circuit or travel due to the presence of a surface tension of the pipes. Referring to FIG. 10 of the present application, the multiple pipes form an evaporating unit 1 at one side thereof, and a condensing unit 2 at another side thereof. The pipes contain therein working fluid having a volume that is less than the volume of the pipes. By capillary effect, the working fluid is randomly distributed in segments along the multiple-loop heat pipe with vapor segments filled between the liquid segments, thereby forming alternately arranged liquid slugs 3 and vapor slugs 4.

During operation, as the evaporating unit 1 is heated, the liquid slugs 3 absorb heat and vaporize to form vapor bubbles. The vapor bubbles and the vapor slugs 4 start to grow and the pressure in the evaporating unit 1 increases so as to push the liquid and vapor slugs 3, 4 and the vapor bubbles to flow toward the condensing unit 2 that has a relatively lower temperature and a relatively lower pressure. The vapor bubbles in the condensing unit 2 condense to liquid to release heat outwards, which lowers the pressure at the condensing unit and therefore enhancing the pressure difference between the evaporating unit 1 and the condensing unit 2. Because of the interconnection of the pipes, the motions of liquid and vapor slugs 3, 4 in one pipe section toward the condensing unit 4 also lead to the motions of the liquid and vapor slugs 3, 4 in a next pipe section toward the evaporating unit 1. The evaporating unit 1 has higher temperature and higher pressure, so any liquid and vapor slugs 3, 4 moving toward the evaporating unit 1 is subject to a restoring force. The interaction between the pushing force and the restoring force leads to oscillation or pulsation of the liquid and vapor slugs 3, 4 along the pipes. A result of the pulsation of the liquid and vapor slugs 3, 4 is that the heat is continuously taken from the evaporating unit 1 to the condensing unit 2 to dissipate outwards. Therefore, this kind of heat pipe is called a “pulsating heat pipe” or “oscillation loop heat pipe”.

In the pulsating heat pipe, the volume change of the working fluid itself generates pressure difference, which drives the working fluid to move. To ensure this movement, one important requirement is that a temperature difference exists between the evaporating unit 1 and the condensing unit 2. For this purpose, the pipe sections of the evaporating unit 1 and the condensing unit 2 need a sufficient length to maintain an efficient heat transfer at the evaporating unit 1 and the condensing unit, thereby maintaining the temperature difference. However, this may cause the pulsating heat pipe to be too bulky to be applied in the electronic products, such as notebook computers, which are required to be smaller and smaller.

In addition, in one computer system, more than one heat source may often need to be cooled. The above-described configuration of the pulsating heat pipe is generally unable to meet this need. Therefore, a heretofore-unaddressed need exists in the industry to address the aforementioned deficiencies and inadequacies.

### SUMMARY OF THE INVENTION

The present invention, in one form thereof, provides a pulsating heat transfer apparatus including a plurality of separate heat receiving portions, at least one heat dissipating portion, and a plurality of capillary pipes. Each heat receiving portion has a flat surface for contacting with a heat source, such as a heat-generating electronic device, for example, a central processing unit (CPU), and defines therein at least one first capillary passage. The at least one heat dissipating portion defines therein at least one second capillary passage. The first capillary passages, the at least one second capillary passage, together with the capillary pipes form a close-looped, serpentine flow channel having capillary effect. Vapor slugs and liquid slugs are distributed in the flow channel. Heat is capable of being transferred from the heat receiving portions to the at least one heat dissipating portion by pulsation of the vapor slugs and liquid slugs.

Other systems, methods, features and advantages of the present invention will be drawn from the following detailed description of the preferred embodiments of the present invention with attached drawings, in which:

### BRIEF DESCRIPTION OF THE DRAWINGS

FIG. 1 is an isometric view of a pulsating heat transfer apparatus in accordance with a preferred embodiment of the present invention;

FIG. 2 is a partly exploded view of FIG. 1;

FIG. 3 is an enlarged view of a circled portion III of FIG. 2;

FIG. 4 is an enlarged view of a circled portion IV of FIG. 2;

FIG. 5 is a cross-section view of a heat receiving portion of FIG. 1 along line V-V thereof;

FIG. 6 is a view schematically showing flow channels of the pulsating heat transfer apparatus in accordance with the preferred embodiment;

FIGS. 7 through 9 are views schematically showing flow channels of pulsating heat transfer apparatus in accordance with alternative embodiments of the present invention; and

FIG. 10 is a view schematically showing a conventional pulsating heat pipe.

### DESCRIPTION OF PREFERRED EMBODIMENT

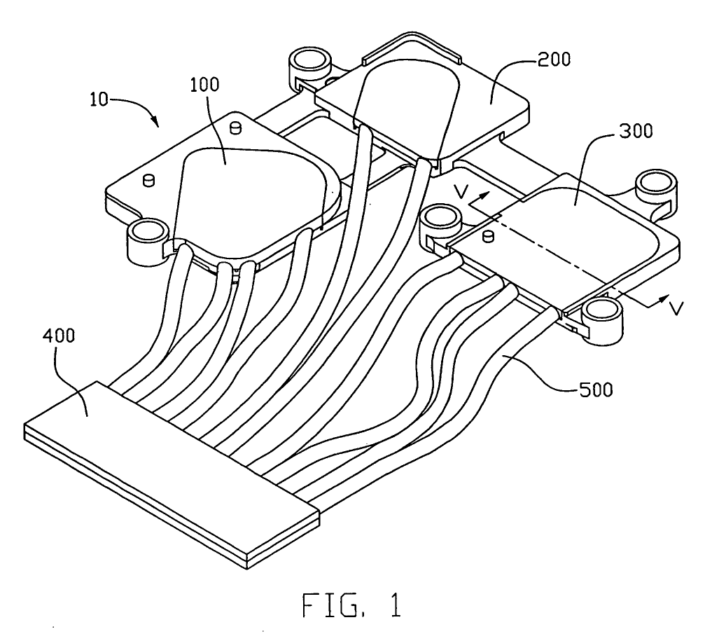

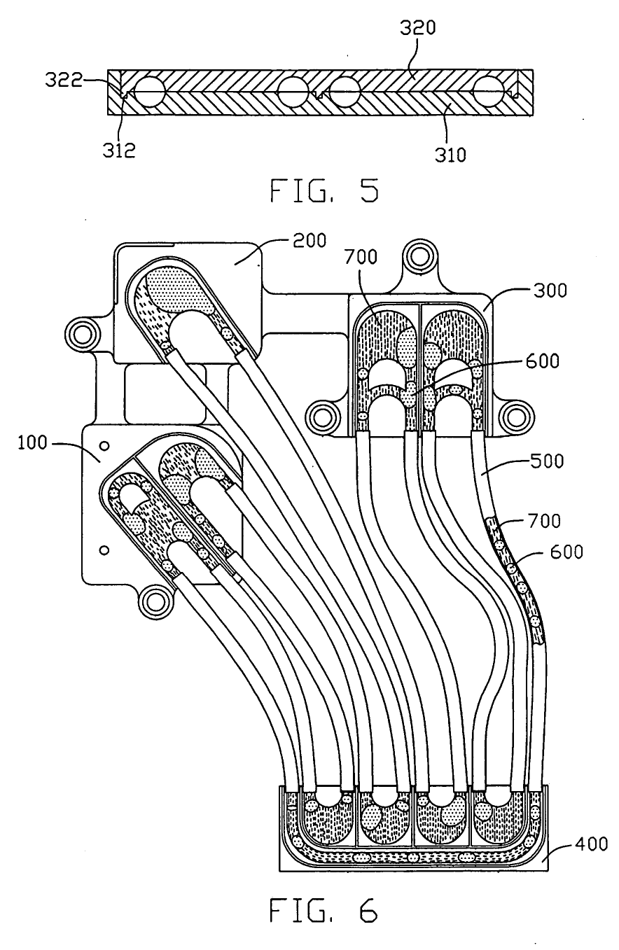

FIG. 1 illustrates by way of example a pulsating heat transfer apparatus 10 (hereinafter “the apparatus 10”) in accordance with a preferred embodiment of the present invention. The apparatus 10 comprises three heat receiving portions 100, 200, 300 and a heat dissipating portion 400. A plurality of capillary pipes 500 connects the heat receiving portions 100, 200, 300 with the heat dissipating portion 400. The heat receiving portions 100-300, the capillary pipes 500 and the heat dissipating portion 400 together define therein a close-looped and serpentine flow channel having capillary effect. Liquid slugs 700 and vapor slugs 600 are alternatively arranged along the flow channel (FIG. 6).

Each of The heat receiving portions 100-300 and heat dissipating portion 400 is configured to be in a plate form. The heat receiving portions 100-300 are used for respectively absorbing heat generated by multiple heat sources (not shown). Pulsating motions of the liquid slugs 700 and vapor slugs 600 continuously take the heat from the heat receiving portions 100-300 to the heat dissipating portion 400, from which the heat is dissipated outwards to atmosphere air. An extra heat radiating device such as, for example, a fined heat sink combined with a cooling fan, or a thermoelectric cooling device, may be coupled to the heat dissipating portion 400 to enhance the dissipating efficiency. Each of the heat receiving portions 100-300 comprises a flat bottom surface to intimately contact a respective heat source. The heat dissipating portion 400 also comprises a flat surface for contacting with the extra heat radiating device.

In this embodiment, there are ten capillary pipes 500 connecting the heat receiving portions 100-300 and the heat dissipating portion 400. Each capillary pipe 500 has a capillary dimensioned inside so as to provide capillary effect. The capillary pipes 500 are discrete components before they are connected to the heat receiving portions 100-300 and the heat dissipating portion 400. The capillary pipes 500 may be soft pipes such as plastic pipes, or hard pipes such as metal pipes.

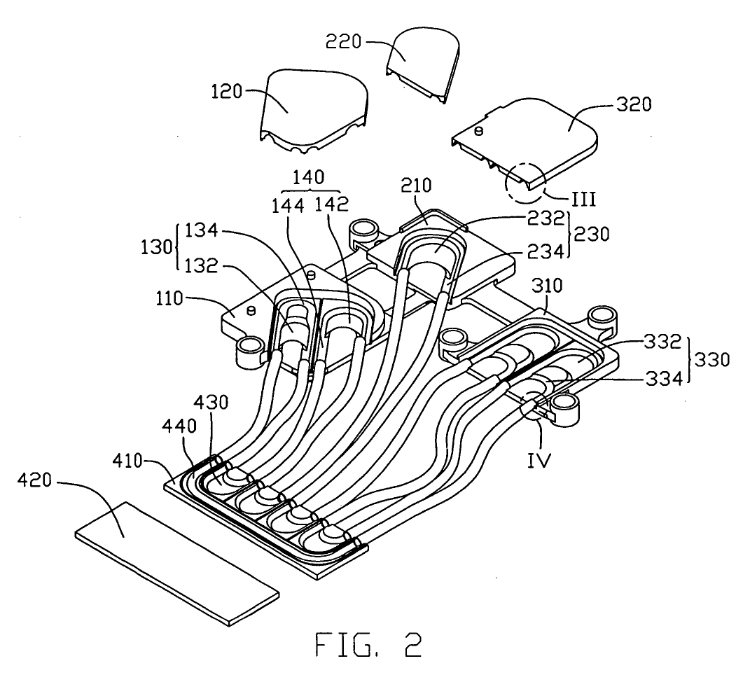

Referring to FIGS. 2 and 6, each of the heat receiving portions 100-300 and the heat dissipating portion 400 is made of highly thermally conductive material such as metal material, for example, copper or aluminum, and comprises two pieces coupled together. For example, the heat receiving portion 100 comprises a base plate 110 and a cover plate 120 coupled to the base plate 110; the heat receiving portion 200 has a base plate 210 and a cover plate 220; the heat receiving portion 300 has a base plate 310 and a cover plate 320; and the heat dissipating portion 400 has a base plate 410 and a cove plate 420. A plurality of capillary passages is formed between these base plates and corresponding cover plates.

The base plate 110 in one surface thereof forms two groove patterns 130, 140. The two groove patterns 130, 140 does not directly communicate with each other. The groove pattern 130 comprises two recesses 132, 134 communicating with each other. The recess 132 has a greater area on the base plate surface than the recess 134 does. The recess 134 has a narrow and arcuate shape, and has two end exits connected to two of the capillary pipes 500. Similarly, the groove pattern 140 comprises a recess 142 having a greater area, and two narrow recesses 144 communicating with the recess 142. The recesses 144 also respectively forms two exits connected to another two of the capillary pipes 500.

The base plate 210 in one surface thereof forms one groove pattern 230. The groove pattern 230 comprises a recess 232 with a greater area, and two narrow recesses 234 communicating with the recess 232. The recesses 234 also respectively forms two exits connected to another two of the capillary pipes 500.

The base plate 310 in one surface thereof forms two identical groove patterns 330 that do not communicate with each other. Each groove pattern 330 comprises a recess 332 with a greater area, and two narrow recesses 334 communicating with the recess 332. The recesses 334 also respectively forms two exits connected to another two of the capillary pipes 500.

Similarly, the cover plates 120, 220, 320 in their surfaces facing the base plates 110, 210, 310 form a plurality of corresponding groove patterns (not visible). As the cover plates 120, 220, 320 are respectively coupled to the corresponding base plates 110, 210, 310, these groove patterns cooperatively form five capillary passages. These five capillary passages comprise ten exits connected respectively to the ten capillary pipes 500.

The base plate 410 and the cover plate 420 in their facing surfaces form four groove patterns 430 (only the groove patterns 430 of the base plate 410 being visible). The shape of the groove patterns 430 is similar to that of the groove patterns of the heat receiving portions 100-300. As the cover plate 420 is coupled to the base plate 410, these groove patterns cooperatively form four capillary passages. These four capillary passages comprise eight exits connected respectively to eight of the ten capillary pipes 500.

In addition to the four capillary passages 430, the heat dissipating portion 400 further forms a narrow capillary passage 440 surrounding the capillary passages 430. The capillary passage 440 comprises two exits connected to the other two of the ten capillary pipes 500. The capillary pipes 500 connect the heat receiving portions 100-300 with the heat dissipating portion 400 in a manner that each of the capillary passages of the heat dissipating portion 400 communicates with two of the capillary passages of the heat receiving portions 100-300, and each of the capillary passages of the heat receiving portions 100-300 communicates with two of the capillary passages of the heat dissipating portions 400. By such configuration, the capillary passages of the heat receiving portions 100-300 and the heat dissipating portion 400, and the capillary pipes cooperatively form the close-looped and serpentine flow channel.

In this embodiment, the groove patterns are formed in the base plates and corresponding cover plates. Alternatively, the groove patterns may be only formed in the base plates or the cover plates.

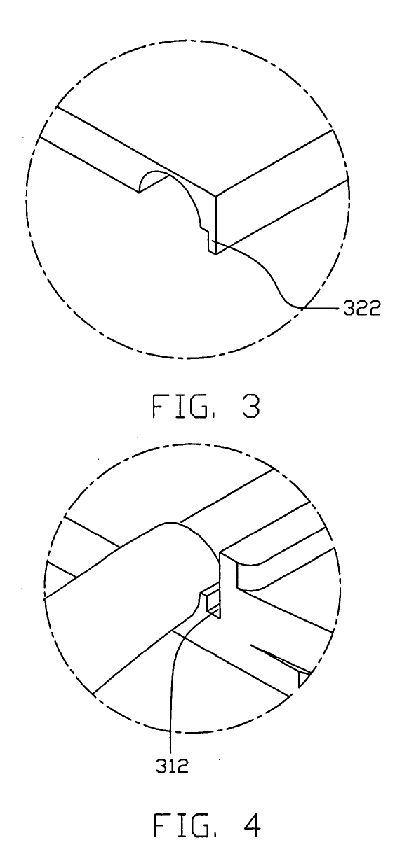

The two pieces of each of the heat receiving portions 100-300 and the heat dissipating portion 400 can be joined using various methods. One feasible method is illustrated as below with reference to FIGS. 3 through 5, taking the heat receiving portion 300 for example.

Referring to FIGS. 3 and 4, the cover plate 320 of the heat receiving portion 300 forms a sealing rib 322, and the base plate 310 forms a coupling slot 312 for receiving the sealing rib 322. A cross section of the sealing rib 322 is slightly greater than that of the coupling slot 312.

Referring to FIG. 5, in coupling the cover plate 320 to the base plate 310, the sealing rib 322 is forcedly inserted into the coupling slot 312 under pressure, so that the sealing rib 322 is interferentially engaged in the coupling slot 312, whereby the cover plate 320 is securely coupled to the base plate 310. Leakage of the working fluid from the heat receiving and dissipating portions 100, 200, 300, 400 is thus prevented.

In addition to the rib-slot coupling structure as described above, the cover plate 320 can also be coupled to the base plate 310 by other means such as, for example, soldering, gluing or sintering. Furthermore, the heat receiving portions or the heat dissipating portion may be integrally formed by die-casting molding technology.

Referring to FIG. 6, vapor slugs 600 and liquid slugs 700 are randomly distributed along the flow channel. Pulsating motions of the liquid slugs 700 and vapor slugs 600 continuously take the heat from the heat receiving portions 100-300 to the heat dissipating portion 400 to dissipate outwards. Since the heat receiving portions 100-300 and the heat dissipating portion 400 each comprises one flat surface, they are able to intimately contact with the heat sources and the extra heat radiating device, respectively, thereby reducing the thermal resistance therebetween. By further configuring them in plates, their sizes become reduced and they become more suitable for being used in the electronic products of low profile.

Along the flow channel, a plurality of chamber sections is formed by the recesses 132, 142, 232, 332, 430, which have greater areas, and a plurality of narrow channel sections is formed by the recesses 134, 144, 234, 334, 440. The chamber sections have a greater cross section than that of the narrow channel sections, which causes a sudden volume change at joints of chamber sections and the narrow channel sections. This sudden volume change further increases the pressure difference and thus reinforces the pulsating motions of the vapor slugs 600 and liquid slugs 700. In addition, a plurality of branching structures is formed at some of these joints. The vapor slugs 600 and the liquid slugs 700 break, converge or branch off at these branching structures. These action of break, converge or branch off further enhance the pulsation of the vapor slugs 600 and the liquid slugs 700. As a result, the efficiency of the heat transfer apparatus is greatly improved.

Furthermore, the presence of the chamber sections and the branching structures increases the contact area between the liquid slugs 700 and the heat receiving portions 100-300, the heat dissipating portion 400, thereby enhancing the heat transfer efficiency therebetween.

In the above embodiment of the heat transfer apparatus, multiple heat receiving portions 100-300 are capable of receiving heat from multiple separate heat sources. The number and position relationship of the multiple heat receiving portions may vary according to the heat sources.

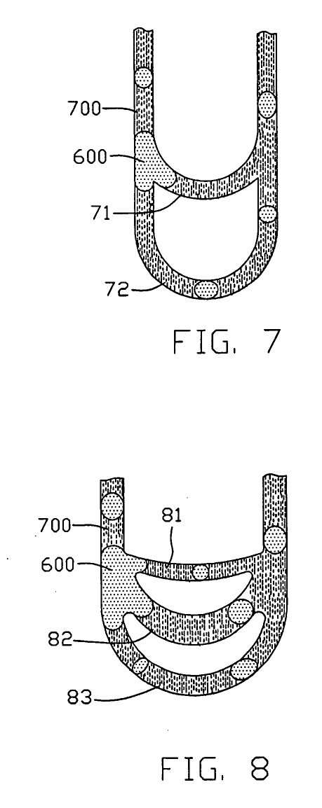

The above embodiment illustrates several types of capillary passages for the heat receiving portions and the heat dissipating portion. More different types of capillary passages are illustrated below with reference to FIGS. 7 through 9. It is noted that these types of capillary passages are exemplary and the capillary passages of the present invention should not be limited to what is disclosed herein.

Referring to FIG. 7, two narrow channel sections 71, 72 are formed in one heat receiving portion or one heat dissipating portion. The narrow channel sections 71, 72 are communicated with each other at two joints thereof and arranged in a parallel manner. Two branching structures are formed respectively at the joints thereof. The vapor slugs 600 and the liquid slugs 700 break, converge or branch off at these branching structures.

Referring to FIG. 8, three narrow channel sections 81, 82, 83 of different cross section area are formed in one heat receiving portion or one heat dissipating portion. The narrow channel sections 81, 82, 83 are arranged in a parallel manner and communicated with each other at two joints thereof. Two branching structures are formed respectively at the joints thereof. The vapor slugs 600 and the liquid slugs 700 break, converge or branch off at these branching structures.

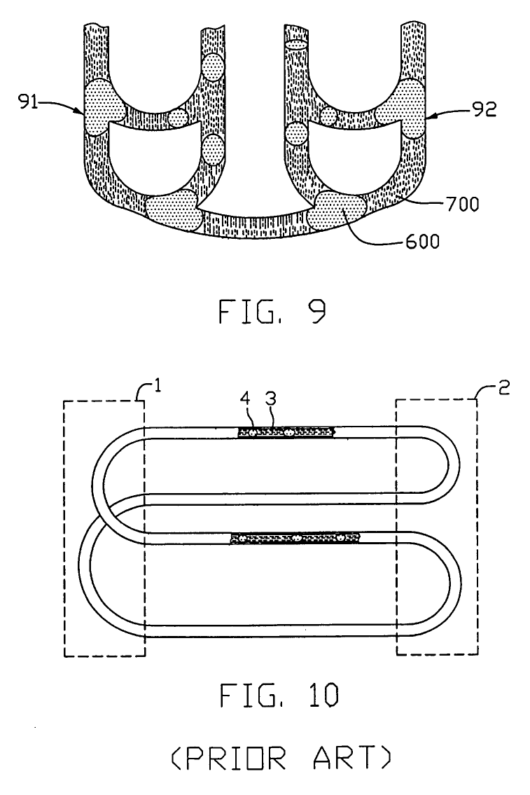

Referring to FIG. 9, two capillary passages 91, 92 are formed in one heat receiving portion or one heat dissipating portion. The capillary passages 91, 92 communicate with each other. Each of the capillary passages 91, 92 comprises two narrow channel sections arranged in a parallel manner as in the capillary passage of FIG. 7. A plurality of branching structures is formed along the capillary passages. The vapor slugs 600 and the liquid slugs 700 break, converge, or branch off at these branching structures.

In the preferred embodiment of the present invention, the heat receiving portions 100-300 are completely made of highly thermally conductive materials. Considering that, on most occasions, the heat receiving portions 100-300 absorb the heat of the heat sources mainly by the base plates 110, 210, 310 contacting the heat sources, the heat receiving portions 100-300 may be configured such that only the base plates 110, 210, 310 are made of highly thermally conductive materials, while the cover plates 120, 220, 320 are made of low cost and readily processed materials such as plastics.

It is understood that the invention may be embodied in other forms without departing from the spirit thereof. The above-described examples and embodiments are to be considered in all respects as illustrative and not restrictive, and the invention is not to be limited to the details given above.

We claim:

1. A pulsating heat transfer apparatus, comprising:
a plurality of separate heat receiving portions, each of which comprising a flat surface for contacting with a heat source, and defining therein at least one first capillary passage;
at least one heat dissipating portion defining therein at least one second capillary passage;
a plurality of capillary pipes connecting the first capillary passages with the at least one second capillary passage to cooperatively form a close-looped, serpentine flow channel having capillary effect; and
vapor slugs and liquid slugs distributed in the flow channel, wherein heat is capable of being transferred from the heat receiving portions to the at least one heat dissipating portion by pulsation of the vapor slugs and liquid slugs.

2. The pulsating heat transfer apparatus of claim 1, wherein the at least one heat dissipating portion comprises a flat surface for contacting with an extra heat dissipating device.

3. The pulsating heat transfer apparatus of claim 1, wherein the heat receiving portions and the at least one heat dissipating portion each are configured to be in a plate form.

4. The pulsating heat transfer apparatus of claim 3, wherein each of the heat receiving portions and the at least one heat dissipating portion comprises a base plate and a cover plate coupled to the base plate.

5. The pulsating heat transfer apparatus of claim 4, wherein one of the base plate and the cover plate forms a coupling slot, and the other of the base plate and the cover plate forms a sealing rib engagingly received in the coupling slot.

6. The pulsating heat transfer apparatus of claim 4, wherein the first capillary passages and the at least one second capillary passage are formed between corresponding base plates and cover plates, respectively.

7. The pulsating heat transfer apparatus of claim 1, wherein each of the first capillary passages comprises at least one chamber section and a narrow channel section communicating with the at least one chamber section at a joint thereof, and a sudden volume change is formed at the joint.

8. The pulsating heat transfer apparatus of claim 1, wherein each of the capillary passages comprises at least two narrow channel sections arranged in a parallel manner and communicated at two joints, and a branching structure is formed at each of the joints.

9. The pulsating heat transfer apparatus of claim 1, wherein each of the at least one second capillary passage comprises at least two narrow channel sections arranged in a parallel manner and communicated at two joints, and a branching structure is formed at each of the joints.

10. A pulsating heat transfer apparatus, comprising:
at least one heat receiving portion defining therein a plurality of first capillary passages;
at least one heat dissipating portion defining therein a plurality of second capillary passages;
a plurality of capillary pipes connected between the at least one heat receiving portion and the at least one heat dissipating portion to form a flow channel having capillary effect, wherein each of the first capillary passages communicates with two of the second capillary passages via a part of the capillary pipes, and each of the second capillary passages communicates with two of the first capillary passages via another part of the capillary pipes, and wherein the capillary pipes are discrete components prior to being connected to the at least one heat receiving portion and the at least one heat dissipating portion; and
vapor slugs and liquid slugs distributed in the flow channel, wherein pulsation of the vapor slugs and liquid slugs is capable of transferring heat from the at least one heat receiving portion to the at least one heat dissipating portion.

11. The pulsating heat transfer apparatus of claim 10, wherein the at least one heat receiving portion is configured to be in a plate form.

12. The pulsating heat transfer apparatus of claim 10, wherein the at least one heat dissipating portion is configured to be in a plate form.

13. The pulsating heat transfer apparatus of claim 10, wherein the flow channel comprises a chamber section defined in one of the at least one heat receiving portion and the at least one heat dissipating portion, and a narrow channel section communicating with the chamber section, and a sudden volume change is formed at a joint of the chamber section and the narrow channel section.

14. The pulsating heat transfer apparatus of claim 10, wherein the flow channel comprises at least two narrow channel sections defined in one of the at least one heat receiving portion and the at least one heat dissipating portion, the at least two narrow channel sections are arranged in a parallel manner and communicated at two joints, and a branching structure is formed at each of the joints.

15. The pulsating heat transfer apparatus of claim 10, wherein each of the at least one heat receiving portion and the at least one heat dissipating portion comprises two pieces coupled together, and the first and second capillary passages are defined between the two pieces.

16. A heat dissipating device for dissipating heat of a heat-generating electronic component, comprising:
at least a heat receiving portion formed of a heat conductive block, having a first capillary passage therein, the at least a heat receiving portion being adapted for contacting the heat-generating electronic component;
at least a heat dissipating portion formed of a heat conductive block, having a second capillary passage therein;
two capillary pipes fluidically connecting the first capillary passage and the second capillary passage to form a closed fluidic loop; and
a two-phase working fluid received in the first, second capillary passages and the two capillary pipes.

17. The heat dissipating device of claim 16, wherein the first capillary passage comprising two fluidically communicating and substantially parallel channel sections.

18. The heat dissipating device of claim 17, wherein one of the channel sections has an area larger than that of the other.

19. The heat dissipating device of claim 18, wherein the heat conductive block forming the at least a heat receiving portion is a flat metal plate.

20. The heat dissipating device of claim 19, wherein the capillary pipes are made of plastics.

21. The heat dissipating device of claim 16, wherein each of the first and second capillary passages comprises a capillary dimensioned inside so as to provide capillary effect.
